(19) United States
(12) Patent Application Publication
(10) Pub. No.: US 2014/0363909 A1
(43) Pub. Date: Dec. 11, 2014

(54) METHOD OF PRODUCING AN ORGANIC LIGHT EMITTING ELEMENT

(71) Applicant: SHOWA DENKO K.K., Minato-ku, Tokyo (JP)

(72) Inventors: Nobuhiro Natori, Tokyo (JP); Haruka Minagawa, Tokyo (JP); Yousuke Fukuchi, Tokyo (JP)

(73) Assignee: SHOWA DENKO K.K., Minato-ku, Tokyo (JP)

(21) Appl. No.: 14/367,100

(22) PCT Filed: Nov. 28, 2012
(86) PCT No.: PCT/JP2012/080693

§ 371 Date: Jun. 19, 2014

(30) Foreign Application Priority Data
Dec. 21, 2011 (JP) 2011-279898

(51) Int. Cl. H01L 51/56; H01L 51/52; H01L 51/00

(52) U.S. Cl. CPC H01L 51/56; H01L 51/0024; H01L 51/5221; H01L 2251/56
USPC 438/29

(57) ABSTRACT

A method of producing the organic light emitting element which includes laminating a first substrate, an anode, an organic compound layer and a light reflective cathode in this order. The organic compound layer includes a light emitting layer, and the method of forming the light reflective cathode includes forming an Al thin layer having a thickness of 0.1 to 10 nm in contact with the organic compound layer and laminating a metal layer having a thickness of 70 nm to 10 μm on one side of the Al thin layer opposite the side in contact with the organic compound layer. The Al thin layer forming step is carried out in a vacuum of 1×10⁻⁸ to 1×10⁻² Pa, and is kept in a vacuum of 1×10⁻⁸ to 1×10⁻² Pa until the metal layer is laminated in contact with the Al thin layer by the metal layer laminating step.

### TECHNICAL FIELD

The present invention relates to a method of producing an organic light emitting element capable of emitting light by applying a voltage on an organic compound layer which is sandwiched between an anode and a cathode.

### TECHNICAL BACKGROUND

An organic light emitting element has a structure such that an organic compound layer such as a light emitting layer made of an organic compound, and the like is sandwiched between an anode and a cathode, and has been expected to be applied to displays and illuminations because of having the advantage of spontaneous light emitting and low electricity consumption. The organic light emitting element emits light in such a way that electron holes and electrons are injected respectively from an anode and a cathode to a light emitting layer and then these electric charges are re-combined, to cause energy and a light emitting material absorbs the energy.

In general, when a barrier for injecting electrons from a cathode to a light emitting layer is lowered, a driving voltage is also lowered. Therefore, a metal having a small work function has been used as a material for forming a cathode. Furthermore, in the case that light emitted from the light emitting layer is taken out to the outside of the organic light emitting element from the anode side, the cathode reflects light and thereby the light emitting efficiency can be improved. As such a cathode, an aluminum (Al) film having a thickness of about 100 nm formed on an organic compound layer by a vacuum deposition method has been conventionally used (for example, referred to Patent document 1). However, high energy is usually necessary for forming Al into a film by the vacuum deposition method. On this account, at the time of forming the cathode, the organic compound layer, particularly the organic compound layer which is near the interface of the cathode deteriorates to cause problems such as lowering of light emitting efficiency and unevenness of brightness in a light emitting surface.

At the time of forming Al into a film, the damage to the organic compound layer can be decreased by not forming an Al cathode on the organic layer directly. For example, as disclosed in Patent document 2, a cathode is separately formed on a substrate by the vacuum deposition method and thereafter is adhered closely to the organic compound layer so that the cathode is formed without exposure of the organic layer to high energy. However, the surface of the Al film formed on the substrate deteriorates even in a vacuum. Therefore, electrons are not injected efficiently even when this surface is adhered to the organic compound layer closely and this method still has a problem such that the light emitting efficiency is low. In addition, the deterioration of the surface of the Al film is considered to be caused by a very slight amount of a residual gas which is present inevitably.

### PRIOR ART DOCUMENT

### Patent Document

Patent document 1: JP-A-H10-511718
Patent document 2: JP-A-H9-7763

### SUMMARY OF THE INVENTION

### Subject to be Solved by the Invention

The present invention is intended to solve the above prior art problems, and it is an object of the present invention to provide a method of producing an organic light emitting element having excellent light emitting efficiency and capable of injecting electrons efficiently from a cathode to an organic compound layer wherein the damage to the organic compound layer is decreased when the organic light emitting element is produced.

### Means for Solving the Subject

The present inventors have been studied earnestly to solve the above subjects, and found that the organic light emitting element having a high light emitting efficiency and a uniform brightness distribution in the light emitting surface can be prepared by using a cathode which is a laminated film obtainable by laminating a thin Al layer directly formed on the surface of an organic compound layer in a vacuum and a metal layer formed on the surface of the Al layer in a vacuum, wherein the cathode has a high electron injection efficiency of Al and light reflectivity, and the damage to the organic compound layer is decreased at the time of forming the cathode.

Thus, the present invention has been accomplished.

That is to say, the method of producing the organic light emitting element of the present invention relates to, for example, the following items (1) to (7).

(1) A method of producing an organic light emitting element obtainable by laminating a first substrate, an anode, an organic compound layer and a light reflective cathode in this order:
wherein the organic compound layer at least comprises a light emitting layer;
wherein a process of forming the light reflective cathode comprises;
(i) an Al thin layer forming step of forming an Al thin layer having a thickness of 0.1 to 10 nm in contact with the organic compound layer and
(ii) a metal layer laminating step of laminating a metal layer having a thickness of 70 nm to 10 μm on one side of the Al thin layer which side is opposite to the other side thereof in contact with the organic compound layer,
   wherein the Al thin layer forming step is carried out in a vacuum of 1×10⁻⁸ to 1×10⁻² Pa; and
   wherein the Al thin layer prepared in the Al thin layer forming step is kept in a vacuum of 1×10⁻⁸ to 1×10⁻² Pa until the metal layer is laminated in contact with the Al thin layer by the metal layer laminating step.
   (2) The method of producing an organic light emitting element according to the item (1):

wherein the Al thin layer forming step is a step of forming the Al thin layer on the surface of the organic compound layer by a vacuum deposition method;

wherein the metal layer comprises at least one metal selected from the group consisting of Ag, Sb, In, Mg, Mn, Pb and Zn or an alloy thereof; and
wherein the metal layer laminating step is a step of forming the metal layer on the surface of the Al thin layer by the vacuum deposition method.
(3) The method of producing an organic light emitting element according to the item (1):
wherein the metal layer laminating step is a step of laminating the metal layer by adhering the metal layer to the Al thin layer with a second substrate; and
wherein the metal layer formed on the second substrate has a thickness of 70 nm to 10 μm.
(4) The method of producing an organic light emitting element according to the item (3):
wherein the metal layer comprises at least one metal selected from the group consisting of Ag, Al and Rh or an alloy thereof.
(5) The method of producing an organic light emitting element according to the item (3) or (4):
wherein the cathode forming step comprises a step of releasing the metal layer from the second substrate after the metal layer laminating step.
(6) The method of producing an organic light emitting element according to the item (3) or (4):
wherein the organic light emitting element has a terminal part in the region containing at least one part of the peripheral area of the first substrate;
wherein the terminal part electrically connects the cathode to a source of electricity;
wherein the second substrate has a wiring part on the same surface of the metal layer;
wherein the wiring part electrically connects to the metal layer;
wherein the wiring part comprises the metal as same as that of the metal layer; and
wherein the terminal part and wiring part are electrically connected in the metal layer laminating step.
(7) The method of producing an organic light emitting element according to any one of the items (1) to (6): wherein the organic compound layer has an electron transporting layer;
wherein the electron transporting layer is in contact with to the Al thin layer; and
wherein the electron transporting layer comprises an alkali metal or an alkali metal compound.

### Effect of the Invention

The organic light emitting element produced by the method of producing the organic light emitting element according to the present invention has a high light emitting efficiency and a uniform brightness distribution in the light emitting surface.

### BRIEF DESCRIPTION OF DRAWING

FIG. 1 is a sectional schematic diagram showing one example of the organic light emitting element produced by the method of producing the organic light emitting element according to the present invention.

FIG. 2 is a sectional schematic diagram showing one example of the organic light emitting element with a terminal part and a wiring part produced by the method of producing the organic light emitting element according to the present invention.

FIG. 3 is a sectional schematic diagram showing another example of the organic light emitting element produced by the method of producing the organic light emitting element according to the present invention.

### EMBODIMENT FOR CARRYING OUT THE PRESENT INVENTION

The method of producing the organic light emitting element according to the present invention is a method of producing an organic light emitting element obtainable by laminating a first substrate, an anode, an organic compound layer and a light reflective cathode in this order: wherein the organic compound layer at least comprises a light emitting layer; wherein a process of forming the light reflective cathode comprises; (i) an Al thin layer forming step of forming an Al thin layer having a thickness of 0.1 to 10 nm in contact with the organic compound layer and (ii) a metal layer laminating step of laminating a metal layer having a thickness of 70 nm to 10 μm on one side of the Al thin layer which side is opposite to the other side thereof in contact with the organic compound layer, wherein the Al thin layer forming step is carried out in a vacuum of 1×10⁻⁸ to 1×10⁻² Pa; and wherein the Al thin layer prepared in the Al thin layer forming step is kept in a vacuum of 1×10⁻⁸ to 1×10⁻² Pa until the metal layer is laminated in contact with the Al thin layer by the metal layer laminating step.

The present invention will be described in detail with reference to the drawings below.

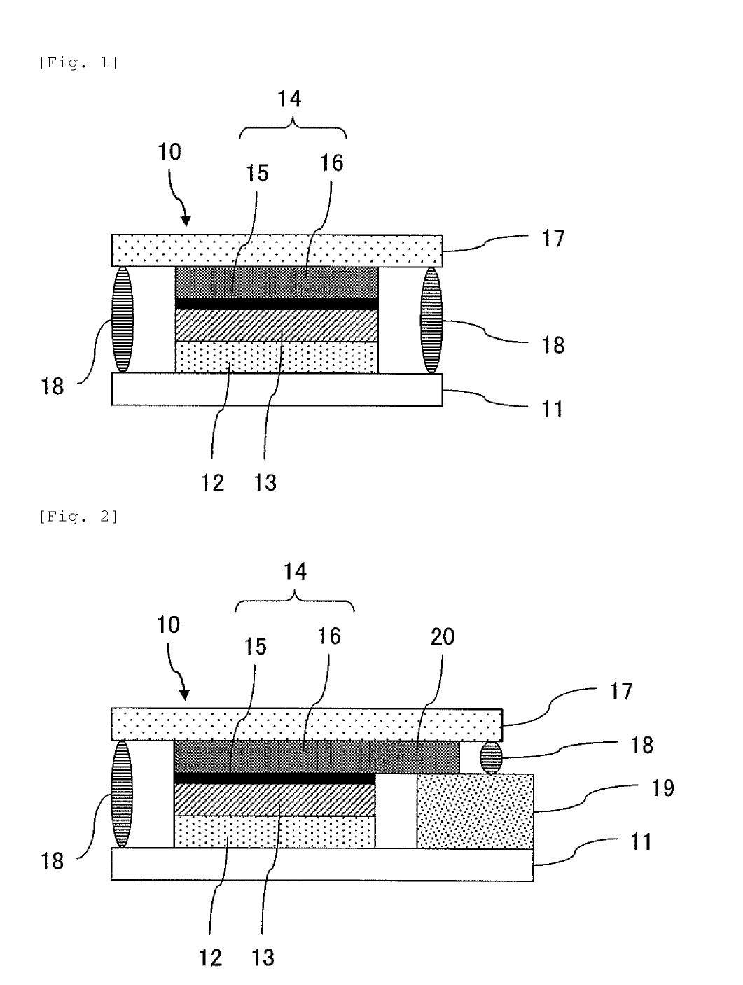

FIG. 1 is a sectional schematic diagram showing one example of the organic light emitting element produced by the method of producing the organic light emitting element according to the present invention. For reasons of convenience, the laminating direction from the first substrate 11 toward the second substrate 17 is determined to be “upward”.

The organic light emitting element 10 has a structure such that on the first substrate 11, an anode 12 for injecting electron holes, an organic compound layer 13 at least containing a light emitting layer and a cathode 14 which injects electrons to the organic compound layer 13 and reflects light emitted in the light emitting layer to the side of the first substrate 11 are laminated successively. The cathode 14 comprises an Al thin layer 15 formed in contact with the organic compound layer 13 and a metal layer 16, and the metal layer 16 is laminated on one side of the Al thin layer 15 which side is opposite to the other side thereof in contact with the organic compound layer 13. The first substrate 11 and the second substrate 17 are fixed by an adhesive member 18 interposed between them.

The first substrate 11 is a support for forming the organic light emitting element 10 having the anode 12, the organic compound layer 13 and the cathode 14, together with the second substrate 17.

In the organic light emitting element 10, the first substrate 11 has to be transparent to light emitted from the light emitting layer in order to emit light from the side of the first substrate 11. Examples of the material used to the transparent first substrate 11 are glasses such as sapphire glass, soda glass and quartz glass; transparent resins such as acrylic resin, polycarbonate resin, polyester resin and silicon resin; metal nitrides such as aluminum nitride and the like; and transparent metal oxides such as alumina and the like. When a resin film made of the above transparent resin is used as the first substrate 11, the resin film preferably has low permeability to water and a gas such as oxygen and the like. When the resin film having high gas permeability is used, it is preferred to form a barrier thin film which suppresses gas-permeation within the limit of largely not marring light permeability.

As light emitted from the light emitting layer is reflected to the side of the first substrate 11 by the cathode 14, not only a material transparent to visible light but also a material nontransparent to visible light can be used as the material used to the second substrate 17. In addition to the above transparent materials, examples of the material used are a simple substance such as silicon (Si), copper (Cu), silver (Ag), gold (Au), platinum (Pt), tungsten (W), titanium (Ti), tantalum (Ta) or niobium (Nb), or an alloy thereof, or stainless steel. When the material of the second substrate 17 has conductivity, an insulating layer may be formed between the cathode 14 and the second substrate to insulate them each other.

The thicknesses of the first substrate 11 and the second substrate 17, which depend on the mechanical strength demanded, are preferably 0.1 to 10 mm, more preferably 0.25 to 2 mm.

The anode 12 injects electron holes to the organic compound layer 13 by applying a voltage between the anode and the cathode 14. The material used for the anode 12 is necessary to have electric conductivity and has a surface resistance in the temperature range of −5 to 80° C. of preferably not more than 1000Ω/□, more preferably not more than 100Ω/□.

A conductive metal oxide, a metal and an alloy can be used as the material having such properties. Examples of the conductive metal oxide are ITO (indium tin oxide), IZO (indium zinc oxide), zinc oxide and tin oxide. Examples of the metal are copper (Cu), silver (Ag), gold (Au), platinum (Pt), tungsten (W), titanium (Ti), tantalum (Ta) and niobium (Nb). Furthermore, alloys containing these metals and stainless steel can be also used. Of these, examples of the material used for the transparent anode are indium oxide, zinc oxide, tin oxide and their complexes such as ITO (indium tin oxide) and IZO (indium zinc oxide), and further gold, platinum, silver and copper. Of these, ITO, IZO and tin oxide are preferred because of having high electric conductivity and capable of easily injecting electron holes to the organic compound layer 13. Moreover, a transparent conductive film made of an organic substance such as poly-aniline or its derivative, and poly-thiophene or its derivative may be used.

In the case that light entered from the light emitting layer would like to be emitted to the outside from the side of the first substrate 11 of the organic light emitting element 10 through the anode 12, the anode 12 has a thickness of preferably 2 to 300 nm in order to have high light permeability. Furthermore, in the case that light does not permeate the anode 12, for example, a pore is formed in the anode layer 12, and light emits from the side of the first substrate 11 of the organic light emitting element 10 through this pore, the anode 12 is formed to have a thickness of 2 nm to 2 mm.

The anode 12 can be formed on the first substrate 11 by a vacuum film forming method such as a vacuum deposition method (resistance heating deposition method, induction heating deposition method or electron beam deposition method), a sputtering method, ion plating method or CVD method, and a coating film forming method such as spin coating method, dip coating method, ink jet method, printing method (screen printing method and the like), spray method or dispenser method.

The organic compound layer 13 comprises one or plural laminated organic compound layers at least containing the light emitting layer, and the light emitting layer comprises a light emitting material capable of emitting light by applying a voltage between the anode 12 and the cathode 14. As the light emitting material, a known light emitting material can be used and any of a light emitting polymer compound and a light emitting non-polymer compound can be used. In the embodiment of the present invention, it is preferred to use phosphorescence organic compounds as the light emitting material, and further it is desired to use a cyclometallized complex from the viewpoint of improving the light emitting efficiency. Examples of the cyclometallized complex are iridium, platinum and gold complexes having a ligand such as 2-phenylpyridine derivative, 7,8-benzoxynoline derivative, 2-(2-thienyl) pyridine derivative, 2-(1-naphtyl)pyridine derivative, and 2-phenylxynoline derivative, and particularly the iridium complex is particularly preferred. The cycylometallized complex may have another ligand except for the ligand which is necessary to form the cyclometallized complex.

Moreover, examples of the light emitting polymer compound are a π conjugated type polymer compound such as a poly-p-phenylene vinylene(PPV) derivative i.e. MEH-PPV(poly[2-methoxy-5-(2-ethylhexyloxy)-1,4-phenylene vinylene], a polyfluorolene derivative and a polythiophene derivative; and polymers having a dye molecule and tetraphenyl diamine derivative or having a dye molecule and triphenylamine derivative in the main chain or the side chain. The light emitting polymer compound and the light emitting non-polymer compound may be used at the same time.

The light emitting layer may contain a host material together with the light emitting material and the light emitting material may be dispersed in the host material. The host material preferably has an electric charge transporting property and is preferably an electron hole transporting compound or an electron transporting compound.

The light emitting layer has a thickness of preferably 1 to 500 nm, more preferably 5 to 250 nm, particularly preferably 10 to 100 nm.

The organic compound layer 13 may have an electron hole transporting layer which receives electron holes from the anode 12 and transports them to the light emitting layer, between the anode 12 and the light emitting layer. As the material for forming the electron hole transporting layer, a known electron hole transporting material can be used and examples thereof are a triphenyl amine derivative such as

TPD(N,N′-diphenyl-N,N′-di(3-methylphenyl)-1,1′-biphenyl-4,4′-diamine),
α-NPD(4,4′-bis[N-(1-naphtyl)-N-phenylamino]biphenyl), m-MTDATA(4,4′,4″-tris[N-(3-methylphenyl)-N-phenylamino]triphenylamine); polyvinyl carbazole; and a polymer compound obtainable by introducing a polymerizable substituent in the above-described triphenylamine derivative and polymerizing. The electron hole transporting material may be used singly or two or more of the electron hole transporting materials may be mixed for use, and plural electron hole transporting layers formed by different electron hole transporting materials may be laminated.

The thickness of the electron hole transporting layer depends on the conductivity thereof so that it is not limited unconditionally. The thickness thereof is preferably 1 nm to 1 μm, more preferably 5 to 500 nm, particularly preferably 10 to 100 nm.

In order to ease the barrier for injecting electron holes from the anode 12 to the electron hole transporting layer, an electron hole injecting layer having a thickness of 1 to 50 nm may be provided between the above electron hole transporting layer and the anode 12. Examples of the material for forming the electron hole injecting layer may include known materials such as copper phthalocyanine, a mixture (PEDOT:PSS) of polyethylene dioxythiophene (PEDOT) and polystyrene sulfonic acid (PSS), fluorocarbon and silicon dioxide, and further may include a mixture of the electron hole transporting material used for the electron hole transporting layer and an electron acceptor such as 2,3,5,6-tetrafluorotetracyano-1,4-benzoquinodimethane (F4TCNQ).

The organic compound layer 13 may have an electron transporting layer which receives electrons from the cathode 14 and transports them to the light emitting layer, between the light emitting layer and the cathode 14. Examples of the electron transporting material used for the electron transporting layer are quinoline derivative, phenanetoline derivative, oxadiazole derivative, perylene derivative, pyridine derivative, pyrimidine derivative, quinoxaline derivative, diphenyl quinone derivative, nitro substituted fluorene derivative, triaryl borane derivative, triadine derivative, triaryl phosphine oxide derivative. Specific examples thereof are tris(8-quinorylight) aluminum (abbreviation Alq), bis[2-(2-hydroxyphenyl)benzo oxazolight]zinc, bis[2-(2-(hydroxyphenyl)benzothiazolite)zinc and 2-(4-biphenylyl)-5-(4-tert-butylphenyl)-1,3,4-oxadiazole.

The electron transporting layer is preferably an electron transporting layer containing an alkali metal or an alkali metal compound, and further preferably comprises a mixture of the above electron transporting material and an alkali metal having a small work function, or an alkali metal salt (alkali metal compound) of the above electron transporting material. Such an electron transporting layer has a high electron mobility and can drive the organic light emitting element 10 at a low voltage. The Al thin layer 15 is formed in contact with this electron transporting layer so that the barrier of injecting electrons can be lowered largely.

As the thickness of the electron transporting layer depends on the conductivity of the electron transporting layer, it is not limited unconditionally. The thickness thereof is preferably 1 to 500 nm, more preferably 5 to 100 nm.

In order to depress passing of electron holes through the light emitting layer and efficiently recombine electron holes and electrons in the light emitting layer, an electron hole blocking layer having a thickness of 1 to 50 nm may be provided between the above electron transporting layer and the light emitting layer. It is understood that this electron hole block layer is one of the layers contained in the organic compound layer 13. The above electron hole block layer is formed using known materials such as triazole derivative, oxadiazole derivative and phenanetroline derivative.

In order to lower the barrier of electron injection from the cathode 14 to the organic compound layer 13 and increase the electron injecting efficiency, a cathode buffer layer may be provided in contact with the cathode 14 on the side of the organic compound layer 13. The material used for the cathode buffer layer is preferably a metal material having a lower work function than that of the cathode 14. Examples of the material may include an alkali metal (Na, K, Rb, Cs), an alkali earth metal (Sr, Ba, Ca, Mg), a rare earth metal (Pr, Sm, Eu, Yb) and a substance selected from fluorides, chlorides or oxides of these metals, and two or more mixtures. The cathode buffer layer has a thickness of preferably 0.1 to 50 nm, more preferably 0.1 to 20 nm, furthermore preferably 0.5 to 10 nm. In the present specification, even the cathode buffer layer made of the inorganic compound is considered to be one layer of the layers constituting the organic compound layer 13 for reasons of convenience.

The organic compound layer 13 can be formed by the procedure same as that of the anode 12. However, the film formation of each layer contained in the organic compound layer 13 is carried out by preferably a resistant heating deposition method or a coating film formation method, and the film formation of the layer containing the polymer organic compound is carried out by particularly preferably the coating film forming method. In the film formation by the coating film formation method, the materials constituting the layer to be formed are dissolved or dispersed in a certain solvent such as an organic solvent, water and the like to prepare a coating solution and the coating solution is used for coating. After the completion of the coating, the coating solution is dried by heating or vacuum suction and thereby the desired layer is formed.

The cathode 14 is a cathode having a property of reflecting light emitted from the light emitting layer, that is to say, having light reflectivity. The cathode 14 has a reflectivity to light emitted from the light emitting layer of preferably 50 to 100%, more preferably 70 to 100%.

In the method of producing the organic light emitting element according to the present invention, the process of forming the light reflective cathode 14 comprises (i) an Al thin layer forming step of forming the Al thin layer 15 having a thickness of 0.1 nm to 10 nm in contact with the organic compound layer 13, and (ii) a metal layer laminating step of laminating the metal layer 16 having a thickness of 70 nm to 10 μm on one side of Al thin layer 15 which side is opposite to the other side thereof in contact with the organic compound layer 13.

In the method of producing the organic light emitting element according to the present invention, the Al thin layer forming step is carried out in a vacuum of 1×10⁻⁸ to 1×10⁻² Pa, and the Al thin layer prepared in the Al thin layer forming step is kept in a vacuum of 1×10⁻⁸ to 1×10⁻² Pa until the metal layer is laminated in contact with to the Al thin layer by the metal layer laminating step. Namely, the Al thin layer is kept in a vacuum of 1×10⁻⁸ to 1×10² Pa in the formation thereof and until the metal layer is laminated after the Al thin layer formation. That is to say, the Al thin layer forming step and the metal layer laminating step are carried out in a vacuum of 1×10⁻⁸ to 1×10⁻² Pa, and further when the method comprises another step between the Al thin layer forming step and the metal layer laminating step, these steps including the another step are carried out in a vacuum of 1×10⁻⁸ to 1×10² Pa. Examples of the another step are a step of inspecting the Al thin layer and a step of conveying the Al thin layer-formed substrate between the Al thin layer forming step and the metal layer laminating step.

In the layers constituting the cathode 14, the Al thin layer 15 is an active layer of injecting electrons to the organic compound layer 13. The Al thin layer 15 is formed in contact with the organic compound layer 13 in a vacuum of 1×10⁻⁸ to 1×10⁻² Pa, so that electron injection can be conducted efficiently without lowering the Al activity as an electron injecting material. Therefore, the Al thin layer 15 is formed using the vacuum film forming method, specifically the vacuum deposition method (resistance heating deposition method, induction heating deposition method or electron beam deposition method), the sputtering method, the ion plating method or the CVD method. Among them, it is preferred to forming the layer by the vacuum deposition method capable of forming a film having a large area and a uniform film thickness.

However, high energy is necessary for forming the Al layer in a vacuum. For example, in the vacuum deposition method, Al has a high evaporation temperature and thereby it is necessary to heat Al at a high temperature for evaporation. Therefore, when Al is formed into a film having about 100 nm for a cathode of a conventional organic light emitting element, there are problems that the organic compound layer is damaged by radiant heat, and thereby the light emitting efficiency is lowered and the brightness distribution in the light emitting surface is uneven. In the present invention, when the Al thin layer 15 is formed to be a thin layer having a thickness of 0.1 to 10 nm, the period of time that the organic compound layer 13 is exposed to high temperatures can be shortened and thereby the damage to the organic compound layer can be depressed while Al keeps the property of efficiently injecting electrons. The Al thin layer having the above described thickness has light permeability. From the viewpoint of further depressing the damage to the organic compound layer 13, the Al thin layer 15 has a thickness of more preferably 0.1 to 5 nm. The film forming rate in the vacuum deposition method depends on the temperature of a deposition source or the distance between the deposition source and the upper surface of the organic compound layer 13 which surface is to be deposited. Therefore, when the Al thin layer 15 is formed to have a thickness in the above described range, the damage to the organic compound layer 13 can be depressed. That is, as when the temperature of the deposition source is increased, the film forming rate is increased, the organic compound layer 13 is more exposed to high temperatures, but the exposed time is shortened.

The metal layer 16 which is one of the layers constituting the cathode 14 is a layer of compensating for the light reflectance and the electric conductivity of the Al thin layer 15 and is formed on one side of the Al thin layer 15 which side is opposite to the other side thereof in contact with the organic compound layer 13. The material used in the metal layer 16 is not particularly limited as long as it has light reflectance and electric conductivity. The material is preferably a simple metal or an alloy. Examples of the simple metal are preferably Ag, Al and Rh which have a high light reflectance in all the visible light regions. The metal layer 16 has a thickness of preferably 70 nm to 10 μm, more preferably 100 nm to 1 μm from the view point of the ease formation thereof and having high light reflectance and electric conductivity.

After the Al thin layer 15 is formed in a vacuum of 1×10⁻⁸ to 1×10⁻² Pa, the metal layer 16 is laminated on the Al thin layer 15 while keeping this vacuum. Through the lamination, high Al activity in the interface between the Al thin layer 15 and the organic compound layer 13 can be kept, and the cathode 14 can be formed.

In the lamination of forming the metal layer 16 on the Al thin layer 15 directly in a vacuum, when Al or a metal which needs higher energy than Al such as Rh is used as the metal constituting the metal layer 16, the organic compound layer 13 is damaged by heat and the like caused by the direct formation of the metal layer 16 on the Al thin layer 15. The damage of the metal layer 16 to the organic compound layer 13 at the time of lamination can be decreased in such a way that the material of the metal layer 16 is separately formed into a film on the second substrate, and this metal layer 16 is piled and adhered on the Al thin layer 16 together with the second substrate 17. The method of forming the metal layer 16 to the second substrate 17 is carried out by the same method as that of the anode 12. The formation of the metal layer 16 to the second substrate 17 is not necessarily carried out in a vacuum. The metal layer 16 may be formed by a coating method in an atmosphere and thereafter adhered with the Al thin layer 15 in a vacuum of 1×10⁻⁸ to 1×10⁻² Pa.

The second substrate 17 is preferably adhered to the first substrate 11 through the adhesive member 18 such as a light curing resin or a thermosetting resin.

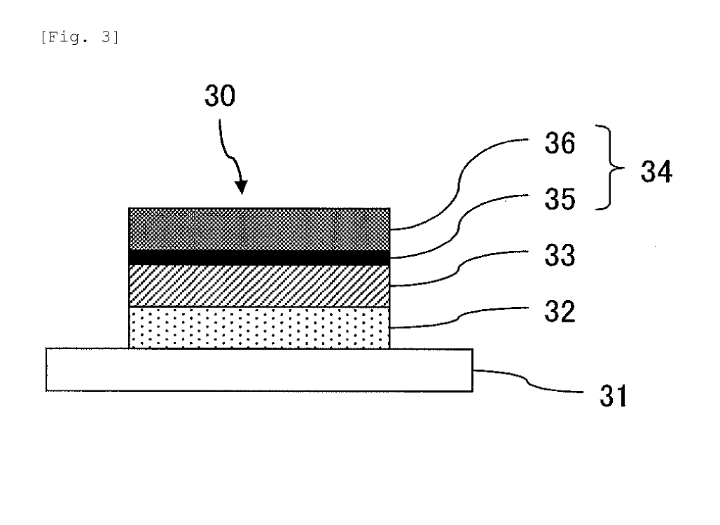

FIG. 2 is a schematic cross-sectional view showing an embodiment of the organic light emitting element containing the terminal part and the wiring part produced by the method of producing the organic light emitting element according to the present invention.

FIG. 2 shows the organic light emitting element 10 as shown in FIG. 1, and also shows the terminal part 19 of electrically connecting the cathode 14 to the source of electricity and the wiring part 20 of electrically connecting the terminal part 19 to the cathode 14. The wiring part 20 is formed together with the metal layer 16 on the same surface as that of the second substrate 17, and the wiring part may be formed by any material as long as the material has electrical conductivity. In the organic light emitting element 10 as shown in FIG. 2, the wiring part 20 is formed by the same material as that of the metal layer 16 and is united with the metal layer 16. That is to say, the wiring part 20 is formed by the same metal as that of the metal layer 16 and is electrically connected to the metal layer. Namely, the wiring part 20 is simultaneously formed together with the metal layer 16 on the second substrate 17 and thereafter when the metal layer 16 is adhered to the Al thin layer 15 closely, the wiring part 20 is electrically connected to the terminal part 19. Through this method, the production method of the organic light emitting element can be more simplified as compared with the separate formation of the wiring part of electrically connecting the metal layer 16 and the terminal part 19. Furthermore, in the case of separately forming the wiring part by the vacuum film forming method, the organic light emitting layer will be damaged by heat and the like, but this method prevents the organic light emitting layer from the damage caused by heat and the like.

In FIG. 2, the thickness of the terminal part 19 is as same as the total thickness of the anode 12, the organic compound layer 13 and the Al thin layer 15 in such a way that the terminal part and the wiring part 20 are in contact with each other. Furthermore, the first substrate 11 and/or the second substrate 17 are made so as to be flexible substrates and thereby the thickness of the terminal part 19 can be formed to be small within the limit that the electrical conductivity is not missed. Moreover, the terminal part 19 and the wiring part 20 may be electrically connected on the overlapping part of them using a conductive adhesive.

The terminal part 19 is formed on the region containing at least one part of the peripheral area of the first substrate 11, and functions electric connecting of the cathode 14 to the source of electricity. Accordingly, the terminal part 19 may be formed by any material having conductivity. The method as same as that of forming the anode 12 can be employed for the method of forming the terminal part 19. Furthermore, the method of producing the organic light emitting element can be simplified by using the material of the terminal part 19 as same as that of the anode 12 and simultaneously forming the terminal part 19 together with the anode 12 at the time of forming the anode 12 on the substrate 11.

The metal layer 16 may be formed by contacting and adhering the metal layer 16 to the Al thin layer 15 and then releasing it from the second substrate 17. When the metal layer 16 is formed in the above manner, a metal foil such that an insulating film such as silicon oxide and the like is formed on the surface or a polyimide sheet is used as the second substrate 17. In this case, the second substrate 17 may have a plate-like or cylinder-like shape. In order to conduct releasing easily, a releasing layer may be formed on the surface of the second substrate 17, or the releasing layer is formed by a material capable of being soften with heating and the metal layer 16 may be formed by any pattern. The releasing step may be conducted in an atmospheric pressure.

In order to use the organic light emitting element 10 for a long period of time stably, it is preferred to provide a protective layer or a protective cover for protecting the organic light emitting element 10 from moisture or oxygen on the outside. The protective layer is provided so as to cover and adhere to the upper part and/or the side part of the organic light emitting element 10. Examples of the material of the protective layer may include a polymer compound, a metal oxide, a metal fluoride, a metal boride, and a silicon compound such as silicon nitride or silicon oxide. Furthermore, these protective layers may be laminated. The protective cover is provided so as to cover and not adhere to the upper part and/or the side part of the organic light emitting element 10. Examples of the material of the protective cover may include a glass plate, a plastic plate having the surface subjected to low permeation treatment and a metal. The protective cover is preferably adhered to the first substrate 11 with a thermosetting resin or a light curing resin, to seal at least the light emitting part of the organic light emitting element 10. The second substrate 17 may serve as the protective cover. It is preferred that an inert gas such as nitrogen, argon or helium is charged in the sealed space because the cathode 14 is easily prevented from oxidation.

FIG. 3 is a schematic cross-sectional view showing one embodiment of the organic light emitting element produced by the method of producing the organic light emitting element according to the present invention. The organic light emitting element 30 has a structure such that on the first substrate 31, the anode 32, the organic compound layer 33 at least containing the light emitting layer and the cathode 34 are successively laminated, and the cathode 34 has the Al thin layer 35 in contact with the organic compound layer 33 and the metal layer 36 formed on one side of the Al thin layer 35 which side is opposite to the other side thereof in contact with the organic compound layer 33. The method for forming the cathode 34 comprises (i) an Al thin layer forming step of forming the Al thin layer 35 having light permeability in contact with the organic compound layer 33 and (ii) a metal layer laminating step of laminating the metal layer 36 having light reflectance in contact with one side of the Al thin layer which side is opposite to the other side thereof in contact with the organic compound layer 33. In the method of producing the organic light emitting element of the present invention, the Al thin layer forming step is carried out in a vacuum of 1×10⁻⁸ to 1×10⁻² Pa and the Al thin layer prepared through the Al thin layer forming step is kept in a vacuum of 1×10⁻⁸ to 1×10⁻² Pa until the metal layer is laminated in contact with the Al thin layer by the metal layer laminating step. In the organic light emitting element 30, the metal layer 36 is separately formed on another substrate except for the first substrate 31 and thereafter is directly formed on the Al thin layer 35 without adhering.

In a similar manner to the Al thin layer 15 of the organic light emitting element 10 as shown in FIG. 1, the Al thin layer 35 in the organic light emitting element 30 is formed to be in contact with the organic compound layer 33 in a vacuum of 1×10⁻⁸ to 1×10⁻² Pa in order to inject electrons to the organic compound layer 33 efficiently. The Al thin layer 35 is formed into a film using the vacuum film forming method. Specifically, it is formed by the vacuum deposition method (resistance heating deposition method, induction heating deposition method or electron beam deposition method), the sputtering method, the ion plating method and the CVD method. Among these methods, the vacuum deposition method is preferred because it easily forms the layer having a uniform thickness in a large area.

The metal layer 36 is a layer which compensates for light reflectance and electric conductivity of the Al thin layer 35 and is formed in a vacuum of 1×10⁻⁸ to 1×10⁻² Pa after the formation of the Al thin layer 35. The material used for the metal layer 36 is a simple metal or an alloy having light reflectivity and electric conductivity and capable of film forming at a lower temperature as compared with Al. Examples of the metal layer 36 are preferably metal layers made of at least one metal selected from the group consisting of Ag, Sb, In, Mg, Mn, Pb and Zn and an alloy thereof. Preferable examples of the metal layer 36 are metal layers made of at least one metal selected from the group consisting of Ag and Pb having high light reflectance in all the visible light regions and an alloy thereof, and a more preferable example is a metal layer made of Ag. The metal layer 36 is formed by the vacuum film forming method, and furthermore it is preferably formed by the vacuum deposition method because the method can be carried out at a relatively lower temperature and can form a film having a uniform thickness in a large area. The metal layer 36 is formed in the above manner so that the damage caused by heat and the like to the organic compound layer can be decreased while the Al layer property of injecting electrons efficiently is maintained.

The metal layer 36 has a thickness of preferably 70 nm to 10 μm, more preferably 100 nm to 1 μm form the viewpoint of easy formation, high light reflectance and high electric conductivity.

The organic light emitting element produced by the method of producing the organic light emitting element according to the present invention is preferably used for image display devices as pixels in a matrix system or a segment system. The organic light emitting element is also preferably used for lighting devices such as a surface emitting source of electricity and the like without formation of pixels.

The organic light emitting element produced by the method of producing the organic light emitting element according to the present invention is specifically used for display devices in a computer, a television, a portable terminal, a mobile phone, a car navigation, a mark, a signboard, a view finder of a video camera and the like, and light irradiation devices in a back light, an electron picture, an illumination, a resist exposure, a reading device, interior illumination, an optical communication system and the like.

### Example

Next, the present invention is described in more detail with reference to the following examples, but it should be not limited by them.

### [Preparation of Light Emitting Material Solution]

A phosphoresce light emitting polymer compound (A) represented by the following formula was synthesized by the method as described in the example of WO2010/016512. The polymer compound (A) has a weight average molecular weight of 52,000 and a molar ratio of each repeating unit k:m:n of 6:42:52.

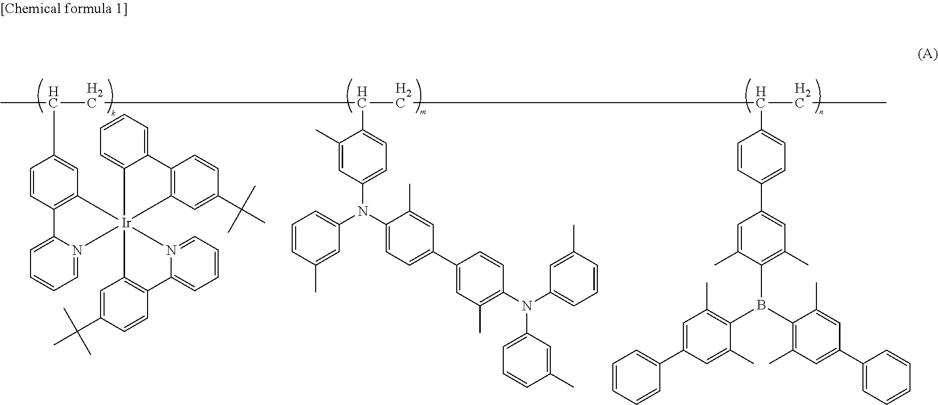

3 Parts by weight of this phosphoresce light emitting polymer compound (A) was dissolved in 97 parts by weight of toluene to prepare a light emitting material solution (hereinafter referred to “solution A”).

### Example 1

An organic light emitting element 10 as shown in FIG. 2 was prepared as an organic light emitting element by the following method.

In the first place, on a glass substrate made of quartz glass having a size of 25 mm square and a thickness of 1 mm as a first substrate 11, an ITO thin film having a thickness of 150 nm is pattern-formed on the light emitting region of the 20 mm square as an anode 12 by the sputtering method using a sputtering device (E-401S manufactured by CANON ANELVA CORPORATION) and simultaneously an ITO film having a thickness of 150 nm was formed on one edge of the glass substrate as a terminal part 19.

Next, on the ITO anode 12, the solution A was applied by a spin coating method (3000 rpm, 30 sec) and allowed to stand for drying at 140° C. for 1 hr in a nitrogen atmosphere to form a light emitting layer having a film thickness of 80 nm as a part of an organic compound layer 13.

Subsequently, using a vacuum deposition device, bathophenanthroline and lithium were co-deposited in a weight ratio of 95:5 on the light emitting layer in a vacuum of 3.3×10⁻⁴ Pa to form an electron transporting layer having a film thickness of 20 nm as a part of the organic compound layer 13.

Next, an Al layer having a thickness of 5 nm was formed as the Al thin layer 15 on the electron transporting layer in a vacuum of 2.1×10⁻⁴ Pa using the vacuum deposition device.

In the meantime, on a glass substrate made of quartz glass having a size of 23 mm square and a thickness of 0.25 mm as the second substrate 17, an Ag layer having a thickness of 70 nm was formed using the vacuum deposition device. After the formation of the Al layer, the Ag layer was adhered with pressure on the glass substrate in such a manner that the Ag layer was in contact with the Al layer and the ITO film as the terminal part 19 in the vacuum deposition device in a vacuum of 2.1×10⁻⁴ Pa, and the first substrate 11 and the second substrate 17 were fixed using a light curing resin to form the Ag layer as the metal layer 16.

On the organic light emitting element 10 thus prepared, a voltage was applied using a constant voltage power source ampere meter (SM2400 manufactured by Keithley Instruments Co.) and the light emitting strength in the direction vertical to the first substrate 11 of the organic light emitting element 10 was measured by a brightness meter (BM-9 manufactured by Topcon Co.). The light emitting efficiency was determined by the ratio of the light emitting strength to the current density, and the light emitting efficiency was found to be 35 cd/A. The distribution of the brightness on the light emitting surface was found to be uniform by visual observation.

### Example 2

The procedure of Example 1 was repeated except for forming an Al layer having a thickness of 120 nm as the metal layer 16 in place of the Ag layer having a thickness of 70 nm to prepare an organic light emitting element 10. The organic light emitting element thus prepared had a light emitting efficiency of 37 cd/A and the distribution of the brightness on the light emitting surface was found to be uniform by visual observation.

### Example 3

The organic light emitting element 30 as shown in FIG. 3 was produced as an organic light emitting element in the following manner.

Firstly, on a glass substrate as the first substrate 31, a light emitting layer as the organic compound layer 33 and an electron transporting layer, and an Al layer as the Al thin layer 35 were respectively formed in the same manner as that of Example 1.

Next, in the vacuum deposition device used in the Al layer formation, after the formation of the Al layer, An Ag layer having a thickness of 100 nm as the metal layer 36 was formed by vacuum deposition while keeping a vacuum of 2.1×10⁻⁴ Pa. The organic light emitting element 30 thus prepared had a light emitting efficiency of 33 cd/A and the distribution of the brightness on the light emitting surface was found to be uniform by visual observation.

### Comparative Example 1

The procedure of Example 3 was repeated expected that the metal layer 36 was not formed, the thickness of an Al layer as the Al thin layer 35 was changed from 5 nm to 100 nm and the Al layer was a light reflective cathode, to prepare an organic light emitting element. The organic light emitting element thus prepared had an average a light emitting efficiency on the light emitting surface of 16 cd/A and the distribution of the brightness on the light emitting surface was found to be not uniform by visual observation.

### DESCRIPTION OF MARK

10 . . . Organic light emitting element
11 . . . First substrate
12 . . . Anode
13 . . . Organic compound layer
14 . . . Cathode
15 . . . Al thin layer
16 . . . Metal layer
17 . . . Second substrate
18 . . . Adhesive member
19 . . . Terminal part
20 . . . Wiring part
30 . . . Organic light emitting element
31 . . . First substrate
32 . . . Anode
33 . . . Organic compound layer
34 . . . Cathode
35 . . . Al thin layer
36 . . . Metal layer

1. A method of producing an organic light emitting element obtainable by laminating a first substrate, an anode, an organic compound layer and a light reflective cathode in this order:
wherein the organic compound layer at least comprises a light emitting layer;
wherein a process of forming the light reflective cathode comprises;
(i) an Al thin layer forming step of forming an Al thin layer having a thickness of 0.1 to 10 nm in contact with the organic compound layer and
(ii) a metal layer laminating step of laminating a metal layer having a thickness of 70 nm to 10 μm on one side of the Al thin layer which side is opposite to the other side thereof in contact with the organic compound layer,
wherein the Al thin layer forming step is carried out in a vacuum of 1×10⁻⁸ to 1×10⁻² Pa; and
wherein the Al thin layer prepared in the Al thin layer forming step is kept in a vacuum of 1×10⁻⁸ to 1×10⁻² Pa until the metal layer is laminated in contact with the Al thin layer by the metal layer laminating step.

2. The method of producing an organic light emitting element according to claim 1:
wherein the Al thin layer forming step is a step of forming the Al thin layer on the surface of the organic compound layer by a vacuum deposition method;
wherein the metal layer comprises at least one metal selected from the group consisting of Ag, Sb, In, Mg, Mn, Pb and Zn or an alloy thereof; and
wherein the metal layer laminating step is a step of forming the metal layer on the surface of the Al thin layer by the vacuum deposition method.

3. The method of producing an organic light emitting element according to claim 1:
wherein the metal layer laminating step is a step of laminating the metal layer by adhering the metal layer to the Al thin layer with a second substrate; and
wherein the metal layer formed on the second substrate has a thickness of 70 nm to 10 μm.

4. The method of producing an organic light emitting element according to claim 3:
wherein the metal layer comprises at least one metal selected from the group consisting of Ag, Al and Rh or an alloy thereof.

5. The method of producing an organic light emitting element according to claim 3:
wherein the cathode forming step comprises a step of releasing the metal layer from the second substrate after the metal layer laminating step.

6. The method of producing an organic light emitting element according to claim 3:
wherein the organic light emitting element has a terminal part in the region containing at least one part of the peripheral area of the first substrate;
wherein the terminal part electrically connects the cathode to a source of electricity;
wherein the second substrate has a wiring part on the same surface of the metal layer;
wherein the wiring part electrically connects to the metal layer;
wherein the wiring part comprises the metal as same as that of the metal layer; and
wherein the terminal part and wiring part are electrically connected in the metal layer laminating step.

7. The method of producing an organic light emitting element according to claim 1:
wherein the organic compound layer has an electron transporting layer;
wherein the electron transporting layer is in contact with to the Al thin layer; and
wherein the electron transporting layer comprises an alkali metal or an alkali metal compound.
